(19) United States
(12) Patent Application Publication
(10) Pub. No.: US 2013/0056044 A1
(43) Pub. Date: Mar. 7, 2013

(54) PHOTOVOLTAIC MODULE FABRICATION WITH THIN SINGLE CRYSTAL EPITAXIAL SILICON DEVICES

(71) Applicants: Kramadhati V. Ravi, Atherton, CA (US); Tirunelveli S. Ravi, Saratoga, CA (US); Ashish Asthana, Fremont, CA (US); Somnath Nag, Saratoga, CA (US)

(72) Inventors: Kramadhati V. Ravi, Atherton, CA (US); Tirunelveli S. Ravi, Saratoga, CA (US); Ashish Asthana, Fremont, CA (US); Somnath Nag, Saratoga, CA (US)

(73) Assignee: Crystal Solar, Inc., Santa Clara, CA (US)

(21) Appl. No.: 13/566,960

(22) Filed: Aug. 3, 2012

Related U.S. Application Data
(60) Provisional application No. 61/514,641, filed on Aug. 3, 2011.
(60) Provisional application No. 61/652,063, filed on May 25, 2012.

(51) Int. Cl. H01L 31/042; H01L 31/18; H01L 31/045

(52) U.S. Cl. 136/245; 136/244; 438/66; 257/E31.117

(57) ABSTRACT

Photovoltaic modules including a plurality of solar cells bonded to a module back sheet are described herein, wherein each solar cell includes a superstrate bonded to a front side of a photovoltaic device to facilitate handling of very thin photovoltaic devices during fabrication of the module. Modules may also include module front sheets and the solar cells may include bottom sheets. The modules may be made of flexible materials, and may be foldable. Fabrication processes include tabbing photovoltaic devices prior to attaching the individual superstrates.

### CROSS-REFERENCE TO RELATED APPLICATIONS

This application claims the benefit of U.S. Provisional Applications Nos. 61/514,641 filed Aug. 3, 2011, and 61/652,063 filed May 25, 2012, both incorporated herein by reference in their entirety.

### FIELD OF THE INVENTION

The present invention relates generally to photovoltaic module fabrication, and more particularly to module fabrication for epitaxially deposited thin single crystal silicon solar cells, including flexible modules and high voltage modules.

### BACKGROUND

Reducing the manufacturing costs of silicon based photovoltaics requires a drastic reduction in silicon usage. One approach to achieving this is to use very thin silicon wafers for fabricating the solar cells. These thin silicon wafers, less than 50 microns thick, are fabricated using a process that makes very efficient use of the silicon. This process includes epitaxial deposition of thin single crystal silicon wafers on single crystal silicon substrates that have been anodically etched to create a thin (less than 2 microns) porous silicon release layer which enables single crystal growth by epitaxy and also enables exfoliation or peeling of the thin silicon wafer from the silicon substrate to create very thin high quality single crystal silicon wafers. However, these very thin single crystal silicon wafers are mechanically fragile and present challenges for handling, processing, testing and packaging of the resulting solar cells to make photovoltaic modules.

There is a need for new and improved methods and equipment for handling, processing, testing and packaging of very thin silicon wafers and solar cells.

Traditional flexible and light weight photovoltaics have been based on thin film technologies such as amorphous silicon and copper indium selenide (CIGS). A significant problem with these technologies is their relatively low energy conversion efficiencies—typically 6 to 8% for amorphous silicon and 10 to 11% for CIGS. In addition, the reliability and long term stability of these products are questionable, especially due to moisture induced degradation. Crystalline silicon wafer based photovoltaics have high efficiency (>15% to ˜18% module efficiencies with >20% cell efficiencies), high reliability based on over 30 years of field experience, and use earth abundant, non-toxic raw materials. However, significant issues exist with conventional crystalline silicon photovoltaics for lightweight, flexible applications such as: fabricating the thin silicon required at low cost; handling the thin silicon during cell and module fabrication; and wafer thicknesses are typically about 180 microns, making the wafers inflexible and subject to breaking when flexed, and if the wafers are mechanically thinned to enable flexibility, the cost of manufacture increases substantially making such products non-competitive in the marketplace.

There are many applications for which small sized (say 1 sq. ft. and smaller) solar modules are desired in markets for advanced charging technologies for portable devices, including solar-powered handsets, cell phones, solar chargers, wireless power units, fuel-cell battery charging products and public charging kiosks. The modules need to provide the correct “high voltage” for the portable devices—voltages of 6 V, 12 V and 24 V are needed. This is also true for battery charging applications. In order to achieve these voltages in small modules the individual solar cells have to be small (roughly between 4 and 8 cm²) and connected in series.

There is a need for new and improved flexible cell structures and methods and equipment for handling, processing, testing and packaging of very thin silicon wafers and solar cells.

### SUMMARY OF THE INVENTION

The present invention provides methods for fabricating photovoltaic modules comprising a multitude of mechanically fragile thin solar cells, including photovoltaic devices less than 50 microns thick. Methods for handling, processing, testing and packaging these mechanically fragile solar cells are described, which do not involve handling unsupported thin silicon wafers. The solar cells described herein include epitaxial single crystal silicon solar cells; furthermore, the teaching and principles of the present invention may apply to very thin epitaxial solar cells comprising other semiconductors such as germanium, gallium arsenide and others. Furthermore, the present invention includes photovoltaic modules comprising thin glass, modules comprising multiple layers of laminated thin glass, and also modules comprising polymer sheets, such as Teflon®, in place of glass.

According to aspects of the present invention, a photovoltaic module, may comprise: a plurality of solar cells; and a module back sheet; wherein each solar cell comprises: a photovoltaic device with a bus bar on a front side of the photovoltaic device, a front tab attached to the front-side bus bar, a superstrate bonded to the front side of the photovoltaic device, wherein the front tab is between the photovoltaic device and the superstrate, and a rear tab attached to a rear side of the photovoltaic device; and wherein the plurality of solar cells are arranged in a planar array and electrically interconnected, and wherein the module back sheet is bonded to the bottom side of the planar array of solar cells. The superstrate may be a glass or polymer sheet. Furthermore, a module top sheet may be bonded to the top surfaces of the superstrates. The photovoltaic module may be made of sufficiently thin and flexible components to allow the module to be folded up.

According to further aspects of the present invention, a method of fabricating a photovoltaic module including a multiplicity of very thin silicon solar cells may comprise: anodizing a single crystal silicon substrate; growing very thin epitaxial silicon on the anodized surface of the silicon substrate; processing the exposed surface of the epitaxial silicon to form front-side structures of the solar cell; tabbing the front-side; bonding the front-side of the solar cell to a thin glass superstrate; exfoliating the solar cell from the silicon substrate; processing the exposed surface of the epitaxial silicon to form back-side structures of the solar cell; testing the solar cell to determine a characteristic current-voltage curve in response to light exposure; sorting the solar cell into a bin based on the current-voltage characteristic; assembling the solar cell with other solar cells from the same bin and interconnecting them to form a solar cell array; laminating the array to a module back-sheet to form a photovoltaic module; and weather-proofing the module. Wherein the weatherproofing may including laminating a protective glass sheet to the top of the module or filling the gaps between solar cells with a sealant.

According to further aspects of the present invention, high voltage flexible panels and methods for making the same are disclosed herein.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIGS. 1-6 are representations of a process for the fabrication of a first type of photovoltaic module, according to some embodiments of the present invention;

FIGS. 7-9 are representations of a process for the fabrication of a second type of photovoltaic module, according to some embodiments of the present invention;

FIG. 10 is a perspective view of the active layers, collecting grid, bus bars and tabs for a solar cell, according to some embodiments of the present invention;

FIGS. 11-21 are representations of a process for the fabrication of a flexible photovoltaic module, according to some embodiments of the present invention;

FIGS. 22-26 are representations of a process for the fabrication of series connected cells to form a compact high voltage module, according to some embodiments of the present invention;

FIG. 27 shows a plan view representation of a 2×5 array of subcells corresponding to the process step of FIG. 24;

FIG. 28 shows a schematic representation of a compact high voltage module corresponding to the device of FIG. 27;

FIGS. 29-31 show a representation of a further process for the fabrication of series connected cells to form a compact high voltage module, according to some embodiments of the present invention;

FIGS. 32-38 are representations of a further process for the fabrication of a first type of photovoltaic module, according to some embodiments of the present invention; and

FIGS. 39-41 are representations of an alternative process for forming ohmic back contacts to a solar device, according to some embodiments of the present invention.

### DETAILED DESCRIPTION

Embodiments of the present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The present invention provides methods for fabricating photovoltaic modules comprising a multitude of mechanically fragile thin solar cells. Some embodiments of the modules of the present invention are light weight flexible modules. Methods for handling, processing, testing and packaging these mechanically fragile solar cells are described, which do not involve handling unsupported thin silicon wafers. The solar cells described herein include epitaxial single crystal silicon solar cells; furthermore, the teaching and principles of the present invention may apply to very thin epitaxial solar cells comprising other semiconductors such as germanium. Furthermore, the present invention includes photovoltaic modules comprising thin glass, modules comprising multiple layers of laminated thin glass, and also modules comprising polymer sheets, such as Teflon®, in place of glass.

An example of a process flow for forming a first embodiment of a photovoltaic (PV) module is as follows.

(1) Single crystal silicon wafers are anodically etched to create a porous silicon layer approximately 2 microns thick.

(2) Thin epitaxial silicon layers are grown on the porous silicon layer utilizing an epitaxial reactor. See U.S. application Ser. No. 13/483,002 filed May 26, 2012, incorporated by reference in its entirety herein, for a description of methods and equipment for epitaxial growth of thin silicon.

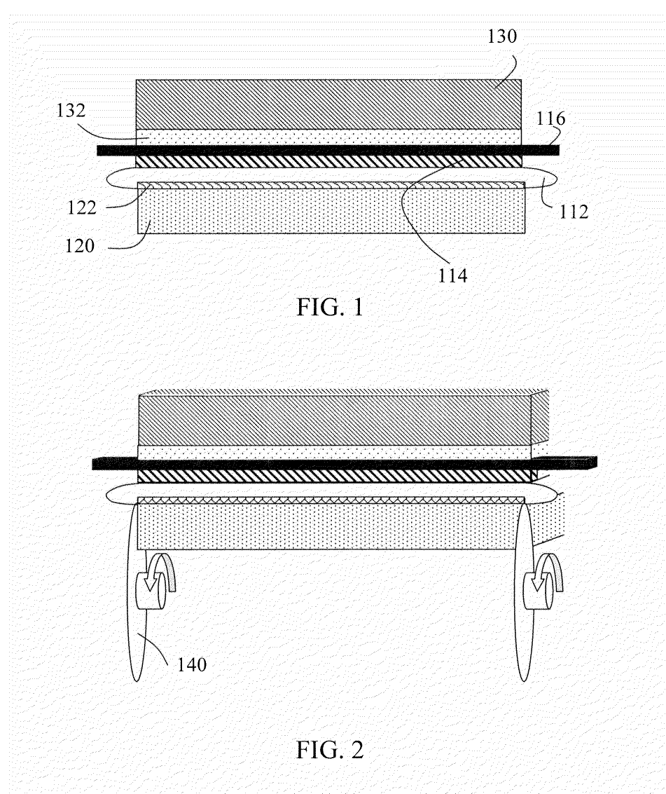

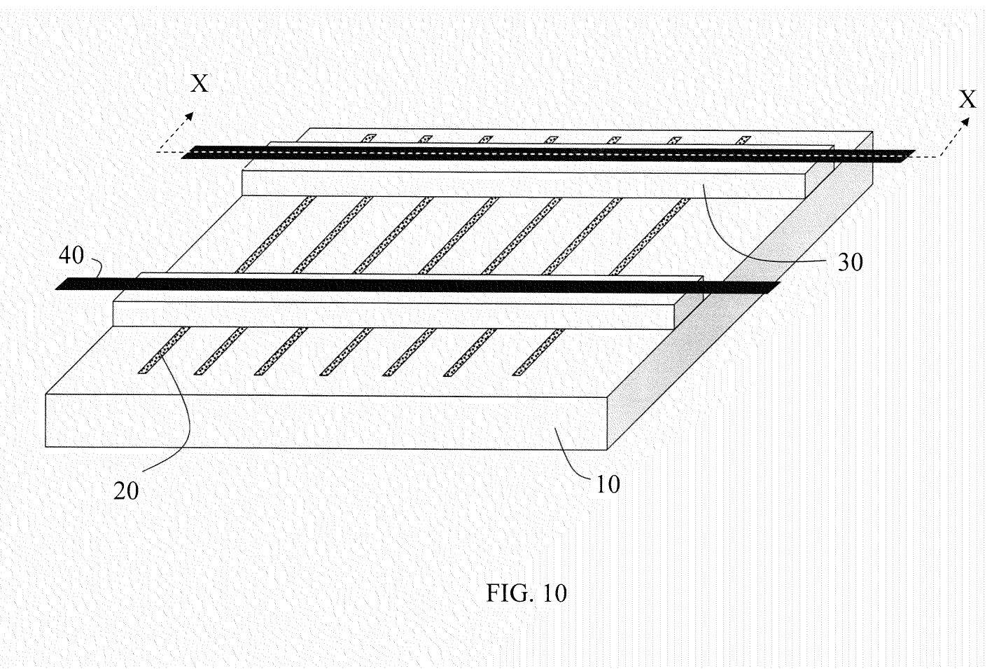

(3) The front side solar cell processing is achieved on the epitaxial film while it is still attached to the silicon substrate. For example, device fabrication may be comprised of: (a) texture etching the surface to minimize reflectivity; (b) forming an n+p junction using, for example, diffusion using phosphorus oxy chloride as the dopant source; (c) removing diffusion induced oxide from the epitaxial film surface by chemical etching; (d) depositing a layer of silicon nitride utilizing, for example, plasma enhanced chemical vapor deposition (PECVD); (e) screen printing a silver metal grid (comprising collecting electrodes and bus bars) on the surface and firing in a furnace to form ohmic contacts; and (f) attaching tabs to the bus bars on the front surface of the solar cell. A perspective view of the general configuration of the active device layers 10, collecting electrodes 20, bus bars 30 and tabs 40 of a solar cell according to embodiments of the present invention is provided in FIG. 10. Only two bus bars per cell are shown in FIG. 10 for simplicity of illustration—there may be more, perhaps 3 bus bars, depending on the cell architecture, or less, just one bus bar per cell; similarly, only 7 collecting electrodes are shown for ease of illustration—there are typically many more, of the order of many tens of collecting electrodes, for example 70. Note that the tabs 40 in FIG. 10 have been minimized for clear illustration—the tabs are actually the width of the bus bars and are much thicker than the bus bars. Furthermore, note that, for the purpose of illustration, FIGS. 1-10 are not drawn to scale. The representations of devices in FIGS. 1-9 show cross sections along the plane defined by X-X in FIG. 10.)

(4) Following front side device fabrication, the wafer is bonded to thin glass (less than 1 mm thick) utilizing ethylene vinyl acetate (EVA). FIG. 1 shows a schematic cross-section of a thin epitaxially deposited silicon device 112 grown on a porous silicon layer 122 on a single crystal silicon substrate 120. The device 112 has bus bars 114 deposited on the device surface and tabs 116 have been attached, making electrical contact to all of the bus bars. See U.S. patent application Ser. No. 13/241,112, filed Sep. 22, 2011, and U.S. Patent Appl. Pub. No. 2012/0040487, both incorporated by reference in their entirety herein, for further details of the fabrication of devices such as shown in FIG. 1. The device 112 has been bonded to a thin glass superstrate 130 using a layer of EVA 132.

(5) The epitaxial edge wrap around the edge of the silicon substrate is removed using dicing saws or lasers. FIG. 2 shows a representation of edge dicing of the device of FIG. 1 using dicing blades 140 to remove epitaxial material that was grown over the edge of the substrate 120. The edge removal process has cutting depth control at least sufficient to avoid cutting the tabs 116. Mechanical grinding tools or plasma etching tools may also be used for the edge removal process.

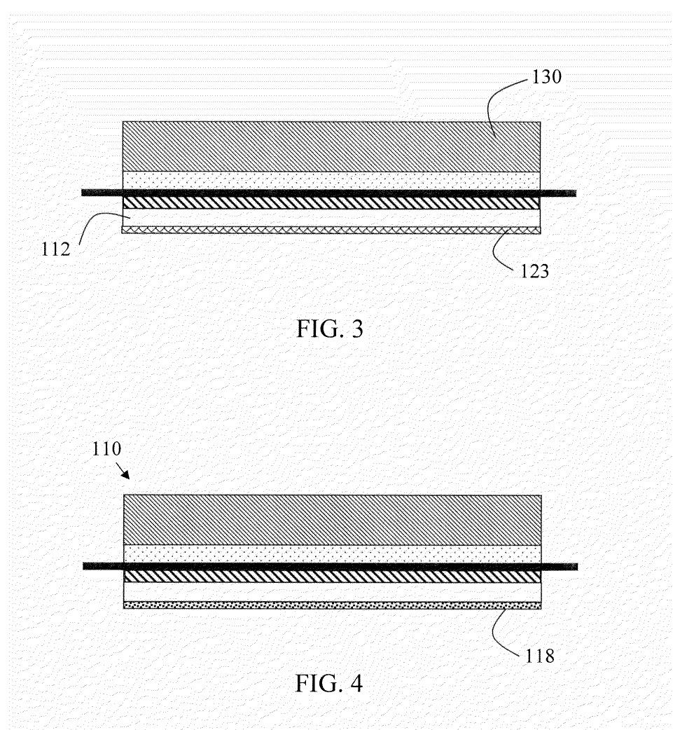

(6) The device is exfoliated from the silicon substrate. FIG. 3 shows a cross-sectional representation of the epitaxial device 112 mounted to glass superstrate 130 after removal of the substrate 120. Remnants 123 of the porous silicon layer 122 will remain attached to the epitaxial device 112 after separation from the substrate 120.

(7) Rear side processing of the solar cell, comprising removing residual porous silicon, deposition of dielectric layers and metal films with laser ablated holes in the dielectric film for point contacts to the back side of the solar cell. FIG. 4 shows the completed and mounted solar cell 110 after the porous silicon remnants 123 have been removed and further metal and dielectric layers 118 have been added to the back side of the device.

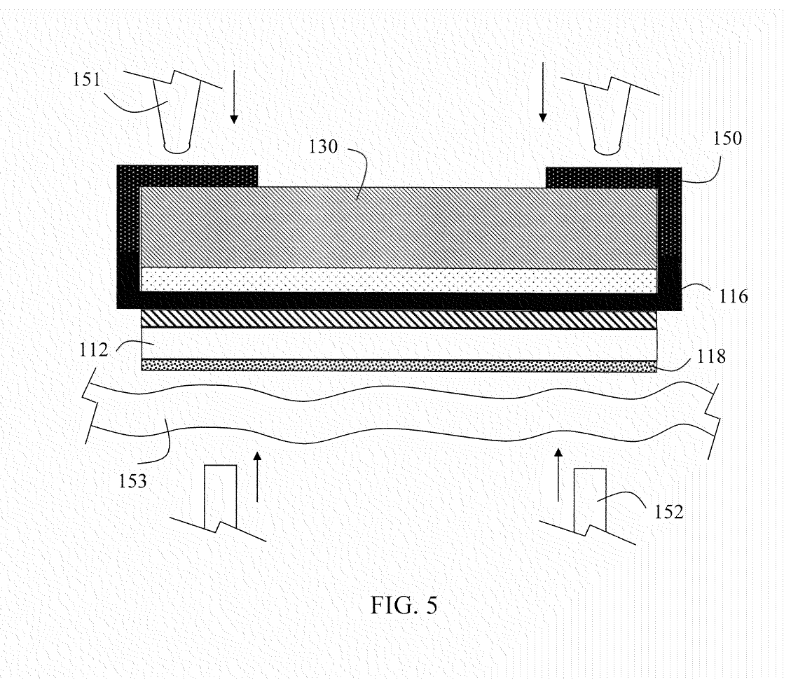

(8) Individual cells (thin silicon on glass) are tested and sorted so that modules may be made up of devices with closely similar characteristics. Individual cell testing involves the measurement of illuminated current-voltage characteristics of the device (I-V curves). This is done using standard solar cell characterization equipment. Solar cell matching is achieved by matching the current at the peak power point of the I-V characteristics. FIG. 5 shows the device of FIG. 4 configured for cell testing. Probes 151 are used to contact interconnect straps 150 which are attached to tabs 116; the interconnect straps may be attached prior to lamination of the device to superstrate 130; the interconnect straps have been bent around the glass superstrate 130 as shown prior to testing. Electrical contact is made to the metal layer in 118 with contact pins 152 from the bottom; to avoid damage of the device layers 112 and 118, a metal foil 153 may be placed between the contact pins and device.

(9) Cells with similar current at peak power point are assembled into series strings of solar cells. Individual strings are connected in parallel to make up the cell array.

(10) The array of cells is laminated to a module back sheet using EVA or a similar bonding agent.

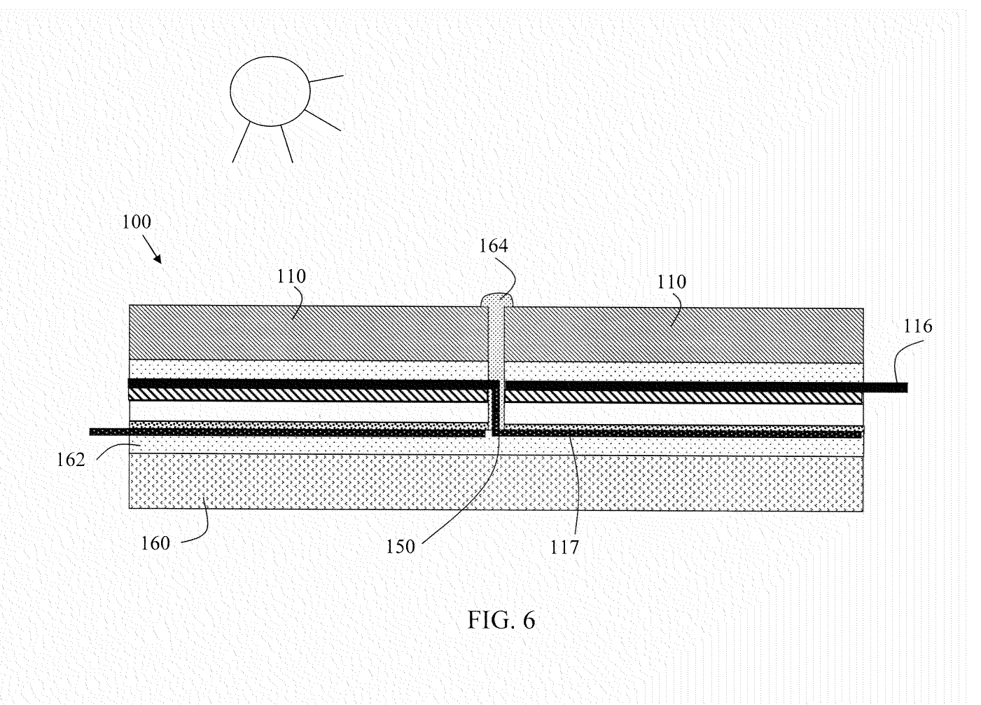

(11) To complete the module fabrication the spaces between solar cells are filled with a low melting temperature glass or other suitable sealing material. FIG. 6 shows multiple mounted solar cells 110 which have been attached to a module back sheet 160 with a bonding agent 162. The tabs 116 and 117 and interconnect straps 150 have been used to series connect the multiple devices. The module back sheet may be a stiff laminated Tedlar® polyvinyl fluoride sheet, fiberglass sheet or even plywood. The bonding agent 162 may be EVA or PVB {poly(vinyl butyral)}. The bonding agent is typically available in sheets that are placed on the solar cell array and then laminated in a lamination chamber—where a bond is formed by application of pressure at elevated temperature. A cell to cell seal 164 may be formed using a low melting point glass, such as a glassy ceramic. Other suitable materials for the cell to cell seal may include EVA, PVB and silicones. The cell to cell sealing material may be applied to the gap between cells using a robotic delivery system, which may include a delivery nozzle moved along the gaps between cells by a robotic device. A cell to cell seal is required for weather-proofing. The total module thickness may be less than 3.5 mm, comprising, for example, in order from top glass to bottom module back sheet: 700 microns glass, 200 microns EVA, 50 microns solar cell, 200 microns EVA and 1 mm module back sheet. Note that the thickness of the top glass (glass superstrates 130) may be varied from less than 1 mm to up to 3 or 4 mm, depending on the amount of impact protection the glass needs to provide. (The solar modules may be used in an environment in which they are exposed to the weather, including hail stones, and other environmental factors, such as dust storms, for a period of 30 years or more—the top glass needs to provide protection against these hazards.) The module is illuminated as indicated in FIG. 6. Note that for simplicity of illustration only 2 cells are shown in the photovoltaic module of FIG. 6—generally modules include 48 to 72 solar cells.

An example of a process flow for forming a second embodiment of a PV module is as follows.

(1) Single crystal silicon wafers are anodically etched to create a porous silicon layer approximately 2 microns thick.

(2) Thin epitaxial silicon layers are grown on the porous silicon layer utilizing an epitaxial reactor.

(3) The front side solar cell processing is achieved on the epitaxial film while it is still attached to the silicon substrate. Device fabrication is comprised of: (a) texture etch the surface to minimize reflectivity; (b) form an n+p junction using, for example, diffusion using phosphorus oxy chloride as the dopant source; (c) remove diffusion induced oxide from the epitaxial film surface by chemical etching; (d) deposit a layer of silicon nitride utilizing, for example, PECVD; (e) screen print a silver metal grid (comprising collecting electrodes and bus bars) on the surface and fire in a furnace to form ohmic contacts; and (f) attaching tabs to the bus bars on the front surface of the solar cell.

(4) Following front side device fabrication the wafer is bonded to a thin glass (less than 1 mm thick) utilizing ethylene vinyl acetate (EVA).

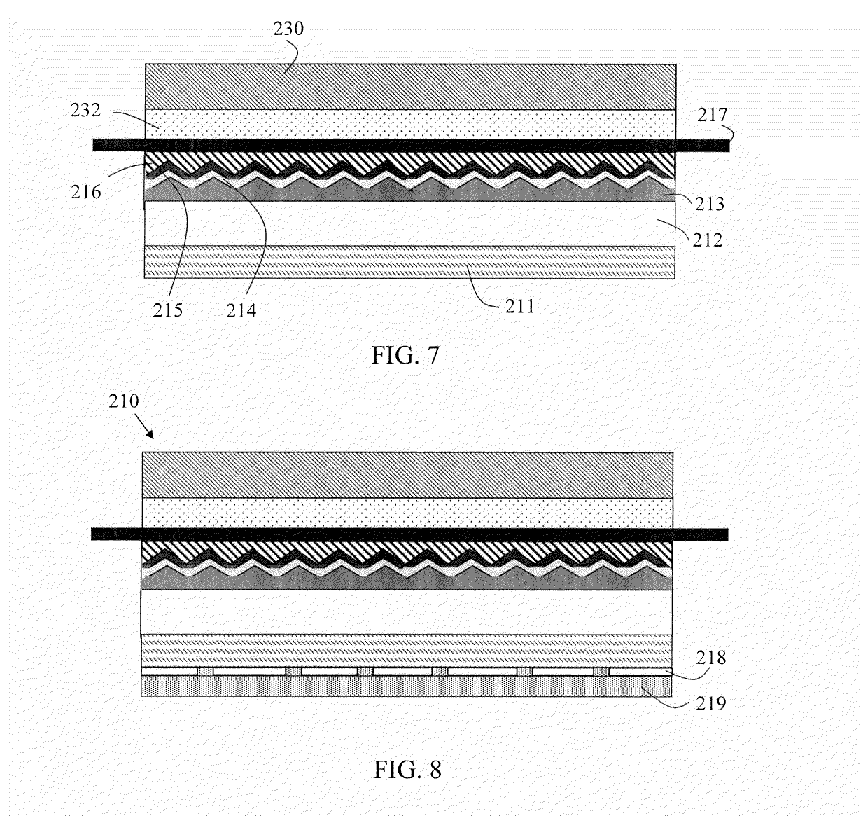

(5) The device is exfoliated from the silicon substrate after removing the epitaxial edge wrap around using dicing saws or lasers. FIG. 7 shows a schematic cross-section of a thin epitaxial silicon device mounted to a glass superstrate 230 using a bonding agent 232, such as EVA. The epitaxial device may have been formed as shown in FIG. 1, edge trimmed as shown in FIG. 2 and then had remnant porous silicon removed. The device of FIG. 7 comprises a BSF layer 211, a p-type epitaxial layer 212, a n+ emitter 213, a silicon dioxide passivation layer 214, a silicon nitride ARC layer 215 and metal contacts 216. See U.S. patent application Ser. No. 13/241,112, filed Sep. 22, 2011, and U.S. Patent Appl. Pub. No. 2012/0040487, both incorporated by reference in their entirety herein, for further details of the fabrication of devices such as shown in FIG. 7. The device has tabs 217 attached for making electrical contact.

(6) The rear side of the solar cell is processed, the processing comprising deposition of dielectric layers and metal films and laser ablating holes in the dielectric film for making point contacts to the back side of the solar cell. FIG. 8 shows completed mounted solar cell 210, which has dielectric layers 218 and back contact 219 with point contacts. Details of the fabrication of this device are provided in U.S. application Ser. No. 13/241,112, filed Sep. 22, 2011, incorporated by reference in its entirety herein.

(7) Individual cells (thin silicon on glass) are tested and sorted so that modules may be made up of devices with closely similar characteristics. Individual cell testing involves the measurement of illuminated current-voltage characteristics of the device (I-V curves). This is done using standard solar cell characterization equipment. Solar cell matching is achieved by matching the current at the peak power point of the I-V characteristics. The testing of solar cells is carried out as described above with reference to FIG. 5.

(8) Cells with similar current at peak power point are assembled into series strings of solar cells. Individual strings are connected in parallel to make up the cell array.

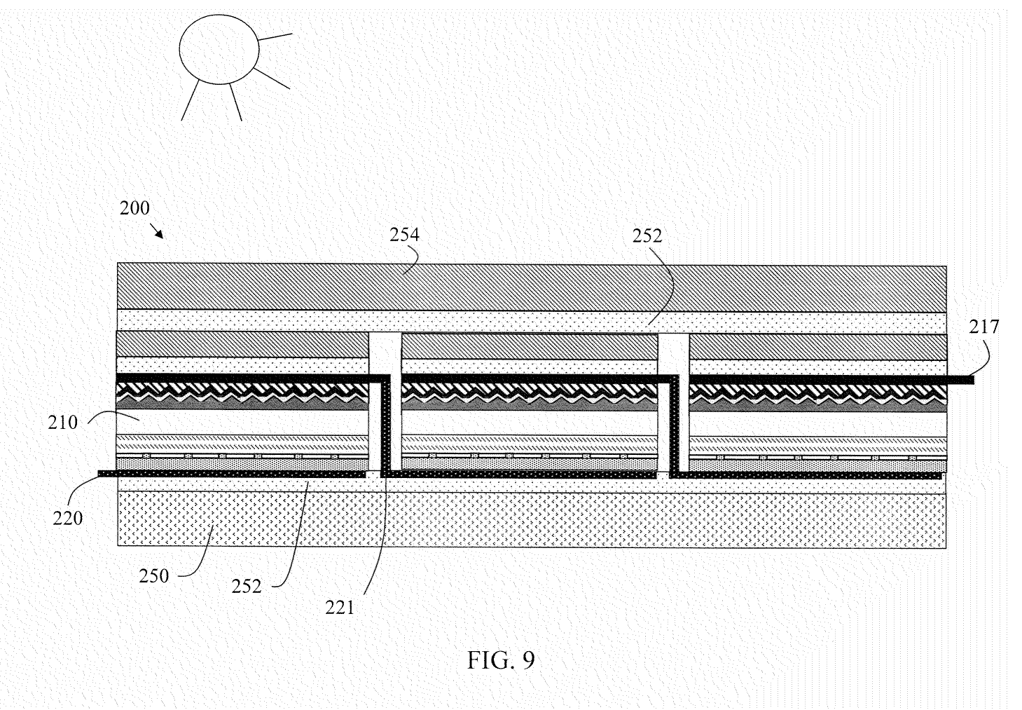

(9) The array of cells is laminated between a glass top sheet and a back sheet using EVA to complete module fabrication. FIG. 9 shows a PV module 200 comprising multiple devices 210 which have been strung together (series connection of devices using tabs 217 and 220, and interconnect straps, 221) and lamination between a module back sheet 250 and a glass top sheet 254 using a bonding material 252, such as EVA. The module back sheet 250 may be glass or another suitable material such as Teflon® sheets. The module is illuminated, through the glass top sheet 254, as indicated in FIG. 9. The total module thickness may be less than 3.0 mm, comprising, for example, in order from top glass down: 1 mm glass, 200 microns EVA, 700 microns glass, 200 microns EVA, 50 microns solar cell, 200 microns EVA and 1 mm module back sheet. Note that for simplicity of illustration only 3 cells are shown in the photovoltaic module of FIG. 9—generally modules include 48 to 72 solar cells.

Although two specific examples of solar cell and module configurations are provided herein, the present invention is generally applicable to the handling, processing, testing and packaging of very thin solar cells to make photovoltaic modules. For example, the present invention is applicable to thin silicon devices with ceramic, glass and glass-bonded ceramic handling layers—see U.S. Patent Appl. Publ. No. 2011/0186117, incorporated by reference in its entirety herein, for details of the fabrication of silicon devices with ceramic, glass and glass-bonded ceramic handling layers—where the handling layer is formed on the thin silicon device prior to separation from the growth substrate. Note for handling layers that are not transparent, the handling layer will be laminated to the module back sheet.

Although the processes and structures described above include thin epitaxial layers which wrap around the edge of the silicon substrate and thus require a dicing step, the teaching and principles of the present invention may also be applied to substrates with epitaxial layers which do not wrap around the edge of the silicon substrate.

Note that a top sheet of glass or other suitable transparent material may be laminated to the top surface of the array of cells in FIG. 6, in order to provide protection and weather proofing, similar to glass top sheet 254 in FIG. 9, in which case the cell to cell seal will not be required. Furthermore, if a top sheet is used, the thickness of the glass superstrates 130 may be reduced, since they are no longer the only material providing impact protection for the active layers of the solar cells. (Multiple sheets—two or more—of thin glass laminated together may be expected to provide better impact resistance than a single sheet of thick glass, even where the total glass thickness is the same, thus providing an opportunity to reduce the overall thickness of the PV module while maintaining good impact resistance. The module with multiple sheets of laminated glass may also be more flexible than the module with only a single sheet of glass.) Similarly, the top sheet of glass 254 in FIG. 9 may be dispensed with if sufficiently thick glass superstrates 230 are used, so as to provide impact protection for the active layers of the solar cell, and the gaps between cells are filled as described with reference to FIG. 6 above.

Note that in principle wherever glass superstrates and glass sheets are used in the embodiments of the present invention they may be replaced with other materials, such as Teflon® sheets available from DuPont and Gorilla® Glass available from Corning; although, use of thin sheets of these materials for flexible modules may require modification of the fabrication process to provide extra support at certain steps, as described in detail below.

According to a third embodiment of the present invention flexible photovoltaic modules are fabricated using thin silicon—typically 50 microns and below—as will be described in detail below. In the present invention the thin silicon is epitaxially deposited. Note that due to using very thin silicon, flexible photovoltaics have reduced efficiency compared with thicker silicon cells due to transmission, rather than absorption, of long wavelength (red) light. However, with good light trapping (back reflectors and front texturing) and surface passivation, efficiencies greater than 19% are theoretically possible even with 25 micron thick silicon wafers.

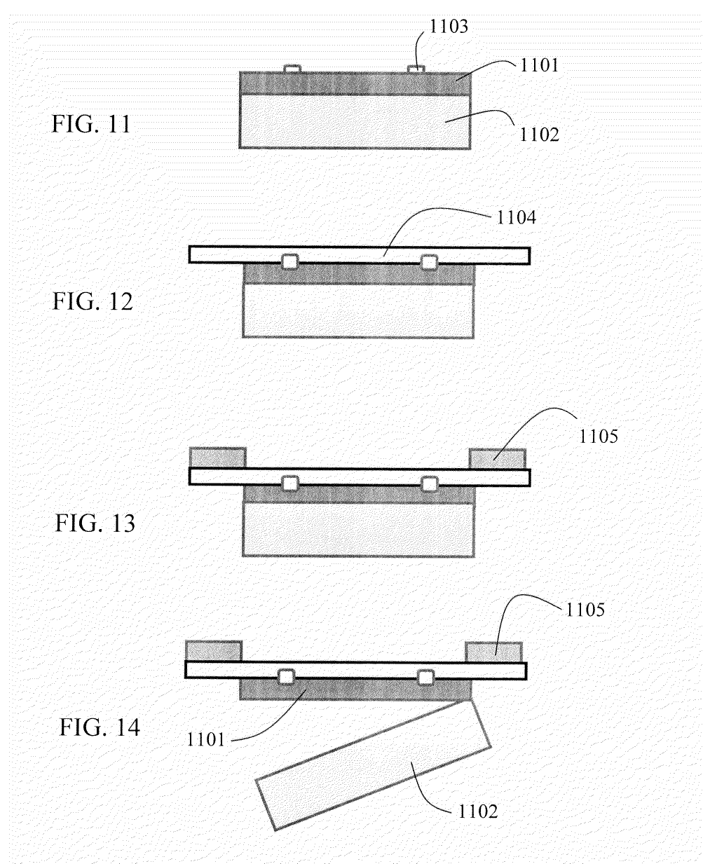

An example of a process flow for forming the third embodiment of a PV module—the flexible PV module—is as follows. FIGS. 11-14 and 16-19 show cross-sectional representations, not drawn to scale, of the fabrication process.

(1) Single crystal silicon wafers are anodically etched to create a porous silicon layer approximately 2 microns thick.

(2) Thin epitaxial silicon layers are grown on the porous silicon layer utilizing an epitaxial reactor.

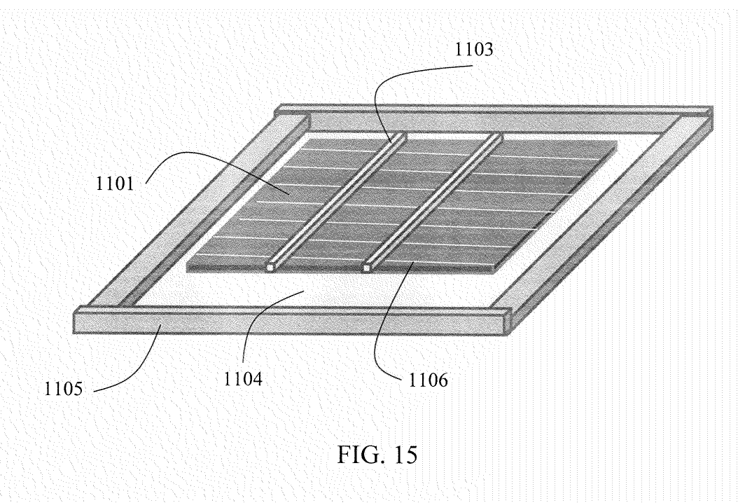

(3) The front side solar cell processing is achieved on the epitaxial film while it is still attached to the silicon substrate. Device fabrication is comprised of: (a) texture etch the surface to minimize reflectivity; (b) form an n+p junction using, for example, diffusion using phosphorus oxy chloride as the dopant source; (c) remove diffusion induced oxide from the epitaxial film surface by chemical etching; (d) deposit a layer of silicon nitride utilizing, for example, PECVD; (e) screen print a silver metal grid (comprising collecting electrodes and bus bars) on the surface and fire in a furnace to form ohmic contacts; and (f) attaching tabs to the bus bars on the front surface of the solar cell. FIG. 11 shows a cross-sectional representation of the thin epitaxial silicon solar cell 1101 formed on the silicon substrate 1102, with bus bars 1103. Note that tabs are attached to the tops of the bus bars as shown in FIG. 10, but for clarity of illustration are not shown in FIGS. 11-19 and 20A; furthermore, collecting electrodes are connected to the bus bars as shown in FIGS. 10 and 15, but for clarity of illustration are not shown in FIGS. 11-14 and 16-21.

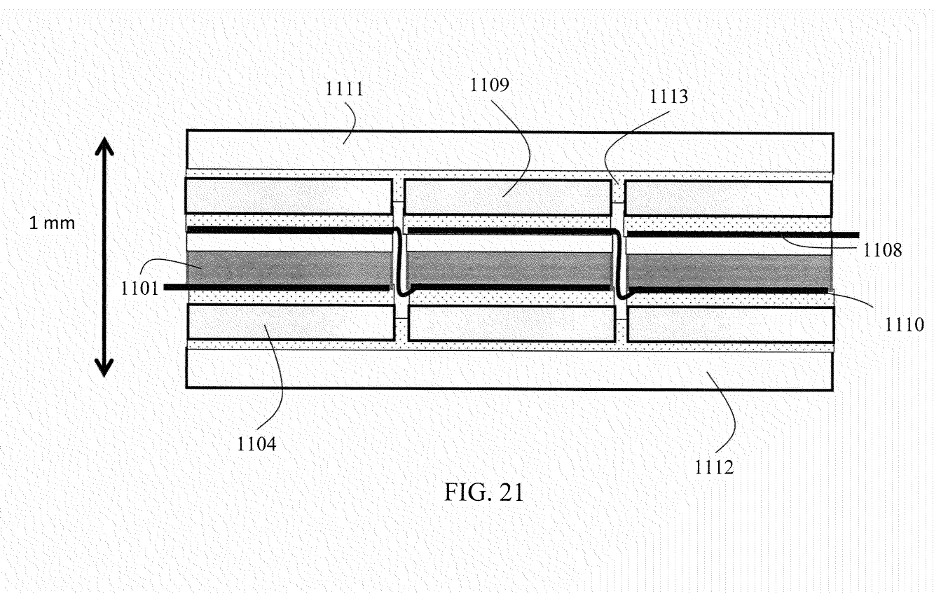

(4) Following front side device fabrication the front side of the wafer is bonded to a thin Teflon® sheet 1104 (typically 50 microns thick) by a lamination process using a bonding agent such as EVA, as shown in FIG. 12. Note that for simplicity of illustration the bonding material is not shown in FIGS. 11-20B; however, it is shown in FIG. 21.

(5) Following lamination the wafer is attached to a frame. The frame is designed to hold the laminate under tension sufficient to keep the laminate flat after exfoliation of the silicon substrate. See FIG. 13 for an example of a square frame 1105 which is attached to the Teflon® sheet by a bonding material between the laminate and the frame. Suitable bonding materials include adhesives and waxes, which may conveniently soften at elevated temperature to release the frame when desired. Alternatively, the frame may comprise two pieces which fit within each other and clamp/cinch the Teflon® sheet in place under tension. Furthermore, the Teflon® sheet may be captured at opposite edges on parallel drums and then tensioned.

(6) The laminate is exfoliated from the silicon substrate, the exfoliation occurring at the porous silicon layer between the substrate 1102 and solar cell device 1101. During and after exfoliation the laminate is kept flat by the frame 1105, as shown in FIG. 14. FIG. 15 shows a perspective view of the laminate held in place by the frame 1105 after exfoliation; note that collecting electrodes 1106, bus bars 1103 and device 1101 are visible through the transparent Teflon® sheet 1104.

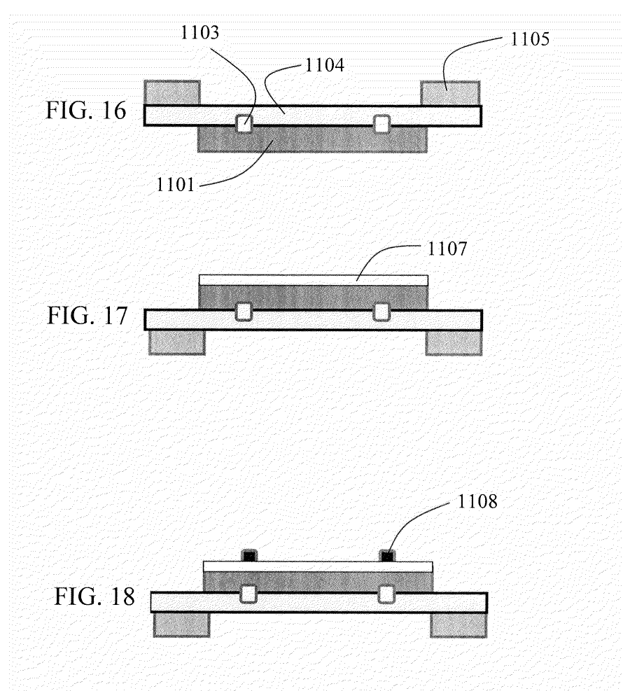

(7) The rear side of the solar cell is processed, as shown in FIGS. 16-18. The processing may comprise deposition of dielectric and metal layers 1107 and attachment of rear tabs 1108. The processing also includes laser ablating holes in the dielectric layer(s) for making point contacts to the rear side of the solar cell.

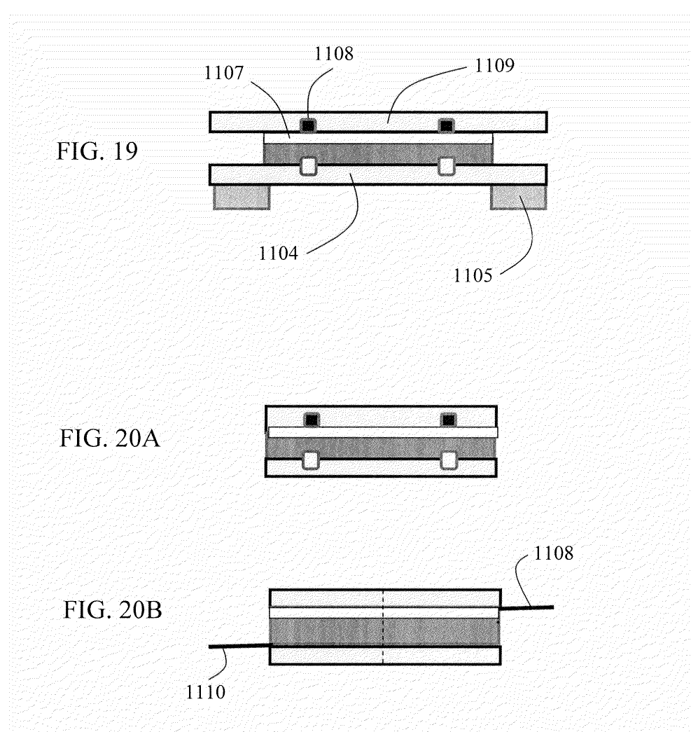

(8) A second Teflon® sheet 1109 is laminated to the rear side of the cell using a bonding material such as EVA, as shown in FIG. 19. (The EVA between the cell and the Teflon® sheet is not shown for ease of illustration).

(9) The frame 1105 is removed by mechanical releasing, softening of the bonding material or by cutting the Teflon® sheet 1104 within the frame, depending on how the frame was attached to the Teflon® sheet. The Teflon® sheets are then cut to size (matching the size of the solar device). The resulting device is shown in cross-section in FIG. 20A, and in side view in FIG. 20B—the latter shows the rear tabs 1108 and front tabs 1110. (The cross-section of FIG. 20A is defined by a plane perpendicular to the page and including the dashed line in FIG. 20B.)

(10) The devices are tested and binned according to their I-V characteristics so that modules may be made up of devices with closely similar characteristics, as described above.

(11) An array of cells is selected as described above and then combined together to form a module. The cells are laminated between a Teflon® top sheet 1111 and a Teflon® back sheet 1112 using EVA 1113. The cells are shown connected in series—tab to tab. See cross-sectional view of FIG. 21. A module such as shown in FIG. 21 may be approximately 1 mm thick. Note that the EVA used to bond the sheets 1109 and 1104 to the solar devices is also shown in this view.

In an alternative embodiment of the above process, at step (4) the silicon device may be bonded to a sufficiently rigid sheet of material to avoid the need for the use of a frame. For example, the Si can be bonded to glass or a stiff sheet, such as a PV5300 ionomer encapsulant sheet available from DuPont. The glass is removed later, after attaching the cells to a back sheet, whereas the PV5300 sheets are part of the finished product, being bonded to a Teflon® front sheet with EVA)—the PV5300 provides the required stiffness at the individual cell level along with the flexibility required of the end product.

The requirements of polymer materials for module cover sheets and back sheets in flexible silicon photovoltaics are: thin and flexible; excellent light transmission characteristics; exhibit good thermal and thermo-mechanical properties; excellent UV resistance; good oxygen and moisture barrier properties and excellent dimensional stability. Note that silicon cells have substantially less stringent packaging requirements when compared with other thin film based flexible PV materials (e.g. CIGS, organic photovoltaics). Materials are available that meet the above requirements, such as DuPont's Teflon® fluoropolymer sheets.

The table below provides examples of flexible module layer thicknesses for modules fabricated according to some embodiments of the present invention. The thicknesses of the different layers are provided for two examples. The first thickness column provides data for a module that may be readily fabricated and the second column provides data for a module that in theory could be fabricated using the teaching and methods of the present invention. As can be seen from the table, the total thickness of these modules can be approximately 1 mm, with prospects for <0.5 mm—compare this with the typical thickness of a conventional rigid, glass based module of approximately 4 mm. (Note that, the example used in the table is for a module of the basic configuration shown in FIG. 9. For a module with the basic configuration shown in FIG. 21, the thickness can be estimated from the table by adding the thicknesses of another fluoropolymer layer and another glue layer.)

| Sheet | Thickness/microns | Thickness/microns |
|---|---|---|
| Fluoropolymer Front Sheet | 125 | 75 |
| EVA Glue Layer | 200 | 100 |
| Fluoropolymer Superstrate | 125 | 50 |
| EVA Glue Layer | 200 | 100 |
| Silicon Solar Cell | 50 | 25 |
| EVA Glue Layer | 200 | 100 |
| Fluoropolymer Back Sheet | 125 | 75 |
| Total Thickness/microns | 1025 | 525 |

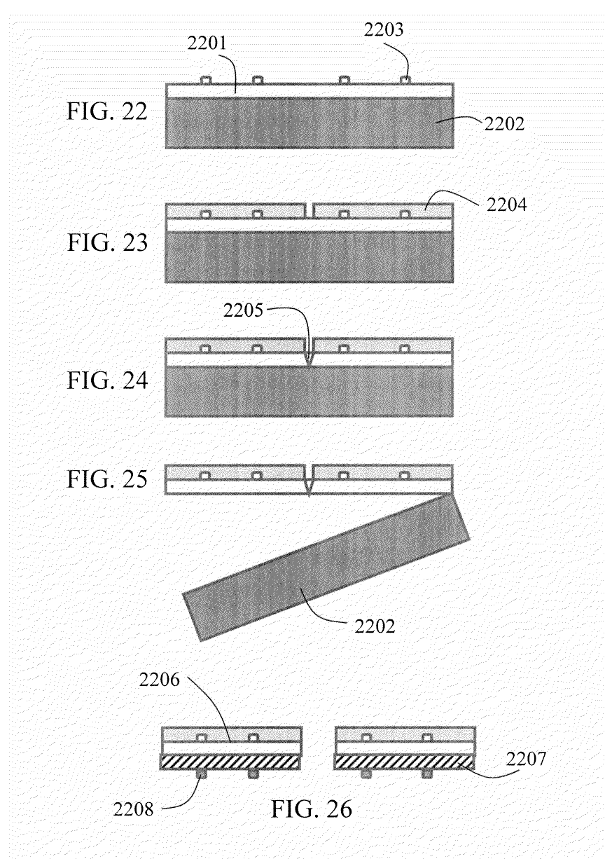

The process flows and structures described herein may all be used to form high voltage (flexible) PV modules; however, some specific examples of process flows and structures for high voltage (flexible) PV modules are provided herein. An example of a process flow for forming a fourth embodiment of a PV module—a high voltage flexible PV module—is as follows. FIGS. 22-26 show cross-sectional representations, not drawn to scale, of the fabrication process.

(1) Single crystal silicon wafers are anodically etched to create a porous silicon layer approximately 2 microns thick.

(2) Thin epitaxial silicon layers are grown on the porous silicon layer utilizing an epitaxial reactor.

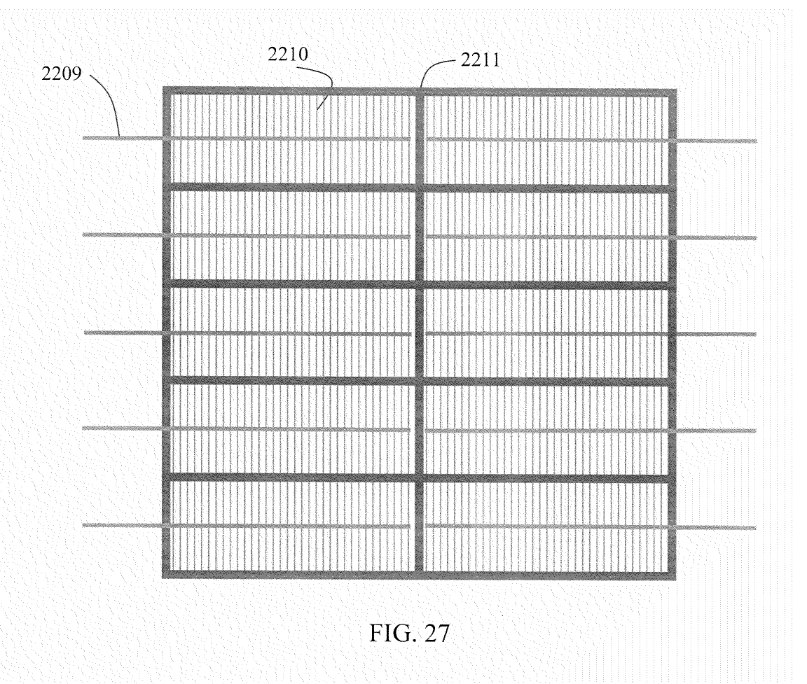

(3) The front side solar cell processing, forming an epitaxial device 2201 is achieved on the epitaxial film while it is still attached to the silicon substrate 2202, as shown in FIG. 22. Device fabrication is comprised of: (a) texture etch the surface to minimize reflectivity; (b) form an n+p junction using, for example, diffusion using phosphorus oxy chloride as the dopant source; (c) remove diffusion induced oxide from the epitaxial film surface by chemical etching; (d) deposit a layer of silicon nitride utilizing, for example, PECVD; (e) screen print metal on the surface using a pattern that will generate multiple sub-cells, each with its own busbar(s) and collecting electrodes and fire in a furnace to form ohmic contacts; and (f) attach tabs to the bus bars 2203 on the front surface of the solar cell using standard solder or low temperature conductive adhesive paste. Note that for simplicity of illustration the front tabs are not shown in FIGS. 22-26. FIG. 27 shows a top view of an example of a substrate after completion of the front side device fabrication. FIG. 27 is an example of a 125 mm cell divided into a 5×2 array of sub-cells each being 1″×2.45″ with one bus bar per sub-cell and a multiplicity of collecting electrodes 2210. Tabs 2209 are attached to the bus bars (hidden under the tabs). Note the gutters 2211 around each sub-cell which are free of screen-printed metal, for ease of separating the sub-cells in a later process step.

(4) Following front side device fabrication the epitaxial device 2201 is bonded simultaneously to a plurality of glass sheets (100 micron thick, for example) or Teflon® sheets 2204 by a lamination process utilizing a bonding material such as EVA. The glass/Teflon® sheets are cut to the sub-cell size and are placed on the surface in alignment with the screen printed electrode pattern and with even gaps (gutters) between the sheets. See cross section of FIG. 23 and plan view of FIG. 27.

(5) Following lamination, the epitaxial film is cut/scribed into individual devices around the borders of the laminated sheets, using a laser, for example, as shown in FIG. 24. The laser cuts through the thickness of the epitaxial silicon—roughly 50 microns—down to the porous silicon, forming scribe lines 2205.

(6) The devices are exfoliated from the silicon substrate 2202, either one at a time or all at once, as shown in FIG. 25, and then separated into individual devices 2206.

(7) The rear sides of the solar cells are processed, as shown in FIG. 26. The processing comprises deposition of dielectric layers and metal films 2207, laser ablating holes in the dielectric film for making point contacts to the back side of the solar cell and rear side tab 2208 attachment.

(8) The sub-cells are tested and binned according to their I-V characteristics so that modules may be made up of devices with closely similar characteristics, as described above.

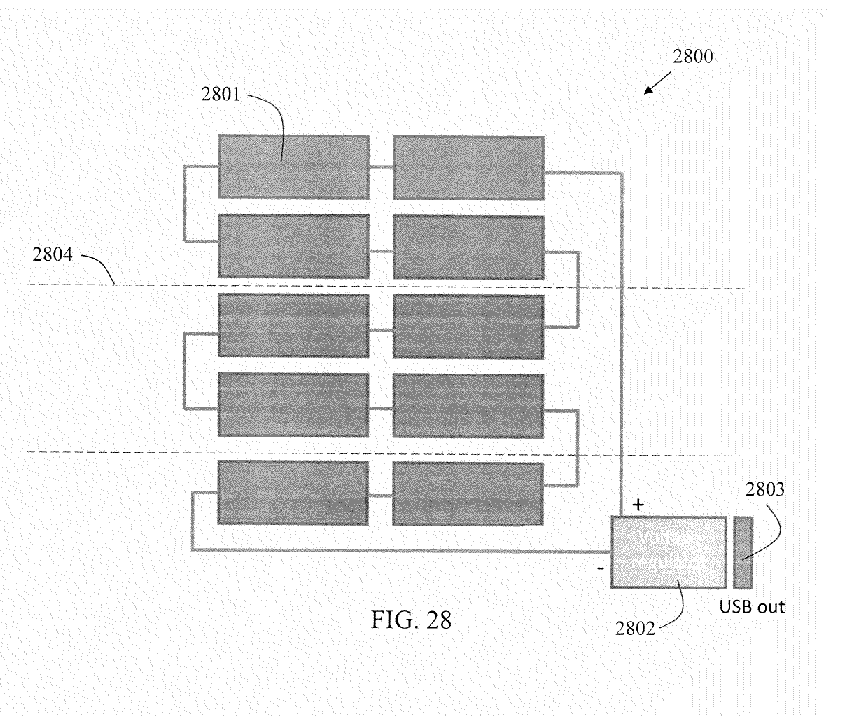

(9) The sub-cells are connected in series and laminated simultaneously to flexible front and back sheets. The flexible sheets may be sheets of fluoropolymers such as Teflon® or Tefzel® ETFE, available from DuPont, for example. FIG. 28 shows a schematic representation of a module with a 2×5 configuration of series connected solar sub-cells 2801. The high voltage module 2800 shown in FIG. 28 is equipped with a voltage regulator 2802 and a USB connector 2803. The USB connector is shown as an example outlet which may be convenient for connection to small electronic devices such as cellular phones, smart phones, etc. These high voltage modules when fabricated from one 125 mm silicon wafer are capable of charging a cell phone—0.6 V×10=6V_{oc}, I_{sc}=0.37 A, 2.5 W. Note the dashed lines 2804 in FIG. 28 which indicate where the module may readily be folded (through 180 degrees); the module may be folded in between sub-cells 2801 where the flexible front and back sheets may act like hinges.

An alternative method of fabricating a high voltage flexible PV module is illustrated in FIGS. 29-31, which is illustrated for a 125 mm wafer to be disaggregated into ten 1″×2.45″ sub-cells. The method starts with front side processing as described above for an array of sub-cells followed by laminating an individual glass/polymer sheet 2905 to each sub-cell using a bonding material 2906, such as EVA. FIG. 29 shows an array of epitaxial silicon devices 2901 formed on a porous silicon layer 2902 on a silicon substrate 2903. Front side bus bars 2904 are shown for each device in the array—the bus bars run perpendicular to the plane of the page. Each bus bar has collecting electrodes (not shown) which run perpendicular to the bus bar over the front surface of the device—see FIGS. 10 and 27 for examples of the bus bar and collecting electrode configuration. Note that tabs are attached to the tops of the bus bars as shown in FIG. 10, but for clarity of illustration are not shown in FIGS. 29-31. A fixture 2907 is attached to the array of individual glass sheets 2906 for holding the array of sub-cells during subsequent processing steps—the fixture may be configured to hold each sub-cell individually, as shown in FIG. 30. The fixture may be based on vacuum, electrostatics, mechanical adhesives or other and may cover partially or entirely the individual front glass pieces. The silicon substrate 2903 is delaminated and then back-side low temperature processing is completed, all while the fixture holds the sub-cells, thus keeping the thin epitaxial silicon devices 2901 from deforming. The back-side processing comprises deposition of dielectric layers and metal films 2908, and laser ablating holes in the dielectric film for making point contacts to the back side of the solar cell. Next, a laser 2909 is used from the backside to cingulate the sub-cells by cutting through the entire 50 micron or so thickness of the epitaxial silicon. FIG. 31 shows the laser cuts 2910. Processing then proceeds as described above. Note that a single busbar is patterned along the length of each sub-cell, with current collecting fingers running perpendicular to the busbar; here the resistance of 0.5″ long fingers (collecting electrodes) will not limit current collected. Further note that the porous Si can be either left in place after substrate removal as a Lambertian light diffractor or may be removed if other optical enhancement techniques are sufficient.

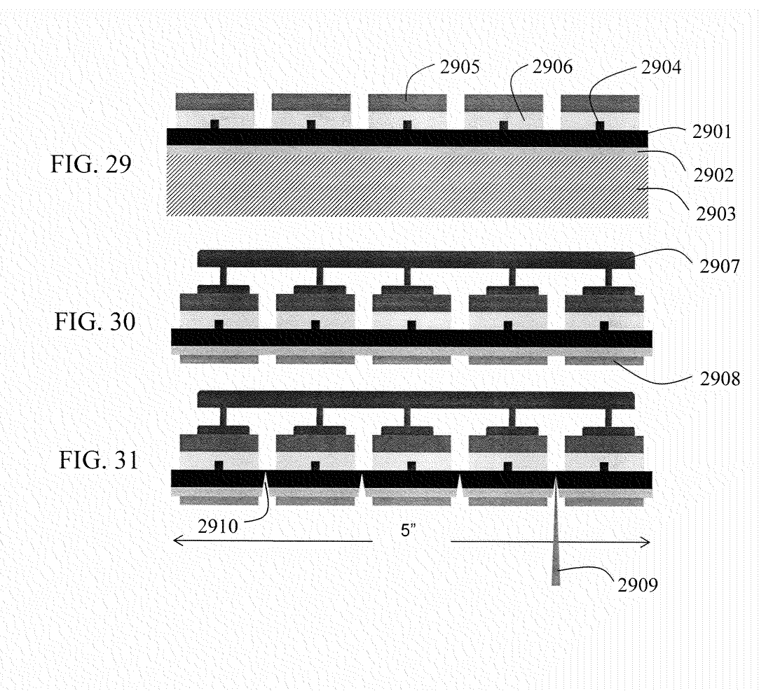

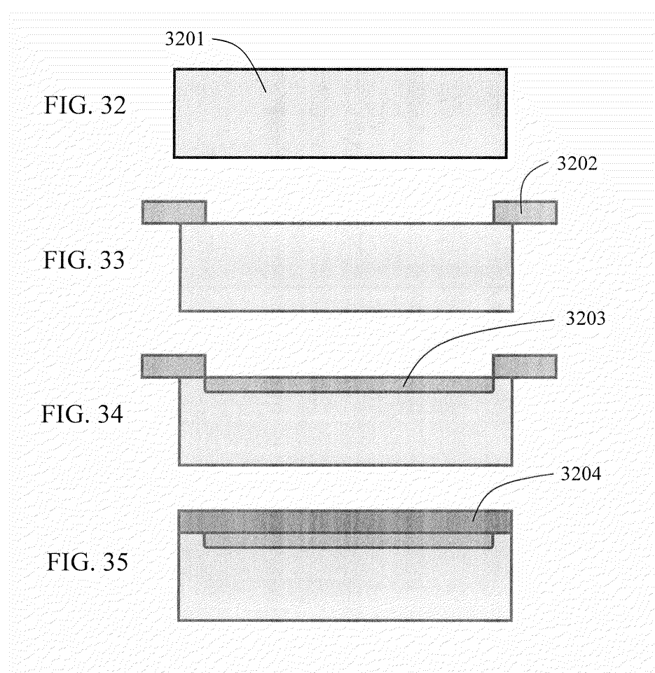

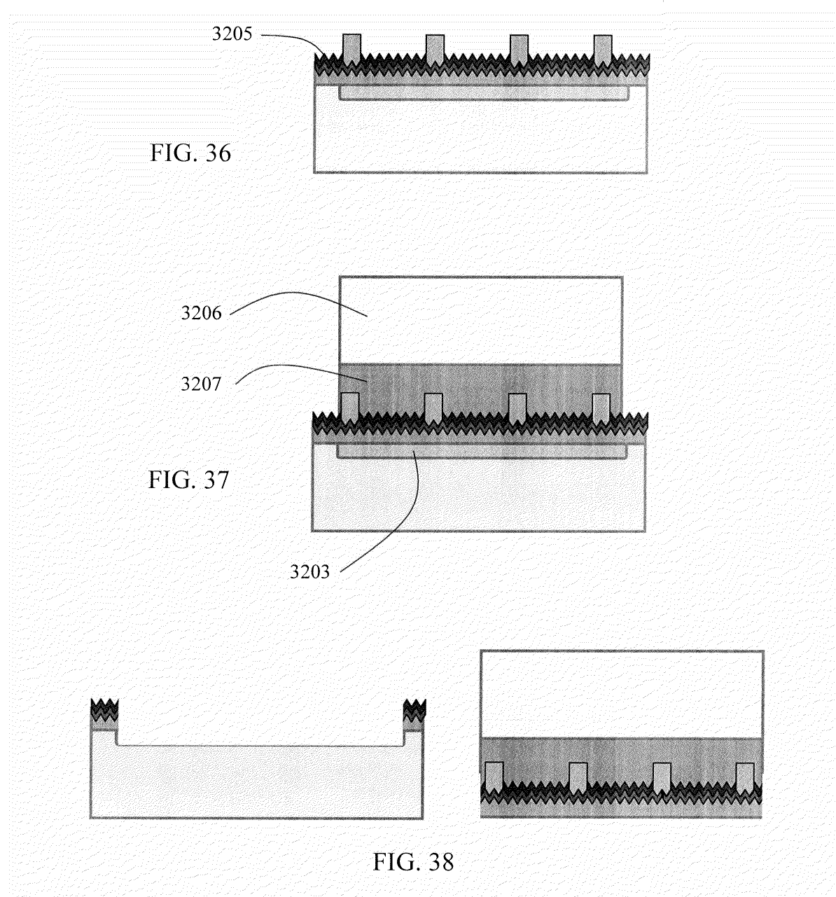

FIGS. 32-38 illustrate a variation in the fabrication process for epitaxially deposited silicon solar devices, according to further embodiments of the present invention. FIGS. 32-38 show cross-sectional representations, not drawn to scale, of the fabrication process. A silicon substrate 3301 is provided as shown in FIG. 32. The edges of the silicon substrate are masked prior to anodization of the silicon surface. FIG. 33 shows a mask 3202 covering the edges of the silicon substrate 3201. The mask is part of a fixture used for holding the silicon substrate during the anodization process. The mask is held in place and forms a fluid seal to the silicon substrate, such that areas under the mask are not exposed to the electrolyte (generally a hydrofluoric acid solution) used in anodization. Suitable mask materials are hydrofluoric acid resistant polymers, such as Teflon®, and the typical width of the masked regions at the edge of the wafer is between 1 and 4 mm. The surface of the silicon substrate is then anodically etched to create a porous silicon layer approximately 2 microns thick in the unmasked area. FIG. 34 shows a porous silicon layer 3203 formed by anodization on the surface of the silicon substrate; the mask protects the substrate edges during anodization so that porous silicon is not formed in masked areas of the substrate surface. The mask is then removed and the substrate is loaded into an epitaxial reactor. A thin film of epitaxial silicon 3204 is grown on the surface of the silicon substrate over the porous silicon layer and crystalline silicon edges of the substrate (where the substrate surface was masked) as shown in FIG. 35. See U.S. application Ser. No. 13/483,002 filed May 26, 2012 for a description of methods and equipment for epitaxial growth of thin silicon. Front side solar cell processing is carried out, as described above; FIG. 36 shows the silicon substrate with a solar device 3205. The solar device is laminated to a thin glass superstrate (less than 1 mm thick) using EVA; the resulting structure with thin glass superstrate 3206 and EVA layer 3207 is shown in FIG. 37. Note that the thin glass superstrate 3206 is sized to match the porous silicon area 3203, and thus has a smaller area than the surface of the silicon substrate. The solar device attached to the thin glass superstrate is exfoliated from the silicon substrate, where the porous silicon acts as a separation layer; FIG. 38 shows the solar device separated from the silicon substrate. Note that, before the exfoliation, a light scribe of the silicon device is performed, using a diamond scribe tool or laser, for example, around the edge of the superstrate where the superstrate is laminated to the solar device. Note that generally in this process flow edge trimming of the solar device is not required, since the portions of the epitaxial silicon device layers attached directly to the silicon substrate, and not to the porous silicon area, remain attached to the silicon substrate during exfoliation. Furthermore, although not shown in FIG. 38, there will be some remnants of the porous silicon layer on both the silicon substrate and the exfoliated solar device.

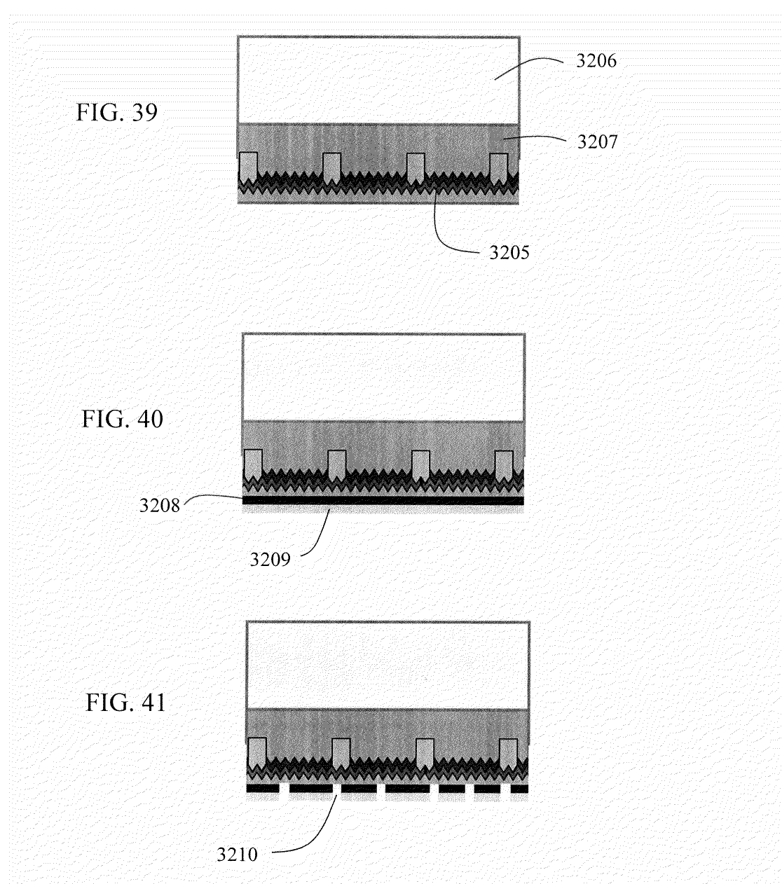

FIGS. 39-41 illustrate a variation in the fabrication process for epitaxially deposited silicon solar devices, according to further embodiments of the present invention. FIGS. 39-41 show cross-sectional representations, not drawn to scale, of the fabrication process. A solar device 3205 with front side processing complete, laminated to a thin glass superstrate 3206 with an EVA layer 3207 is provided as shown in FIG. 39. The solar device comprises epitaxially deposited silicon layers, where the silicon layer on the rear side of the device is an epitaxially deposited highly-doped silicon layer, which functions as a BSF layer. The highly doped epitaxial silicon layer may be deposited with a resistivity of 0.1 ohm-cm or less. A dielectric stack 3208—for example, 20 nm of an oxide, such as silica, and 70 nm of a nitride, such as silicon nitride—is deposited on the rear side of the solar device, followed by a layer of metal 3209, for example, an aluminum alloy, as shown in FIG. 40. Contact regions 3210 are formed through the metal layer and dielectric stack, for making ohmic contact to the BSF layer in the solar device, as shown in FIG. 41; the formation process utilizes a laser, which is used to create roughly 100 micron diameter contact regions. Good ohmic contact is achieved without the need for thermal treatment after aluminum deposition; furthermore, since the BSF is highly doped, there is no need to diffuse aluminum metal into the silicon of the solar device. Furthermore, the density of roughly 100 micron diameter laser drilled holes, and thus rear side contacts, may be as low as 1 per mm², or even lower, due to the low electrical resistivity of the highly doped epitaxial silicon BSF layer.

The methods for fabricating solar modules described herein may be adapted for fabrication of either conventional modules or bifacial modules. Bifacial modules have transparent encapsulant materials (such as DuPont™ ETFE) on both sides enabling light to enter the module from the front sun facing side and reflected light to enter the rear.

The modules described herein describe attaching polymer sheets to solar devices/sub-cells using a bonding agent such as EVA. However, according to further embodiments of the present invention polymer sheets might be bonded directly to solar devices/sub-cells without the use of a bonding agent. It is expected that a combination of elevated temperature and pressure may be used for such a direct bonding process.

Although the solar cells described herein are thin epitaxial single crystal silicon solar cells, the teaching and principles of the present invention may apply to thin epitaxial single crystal solar cells comprising other semiconductors such as germanium, gallium arsenide and others. Furthermore, the teaching and principles of the present invention may apply to standard CZ wafers which can also be cut into pieces of the type described herein and encapsulated in a flexible module as taught herein.

Although the present invention has been particularly described with reference to certain embodiments thereof, it should be readily apparent to those of ordinary skill in the art that changes and modifications in the form and details may be made without departing from the spirit and scope of the invention.

What is claimed is:

1. A photovoltaic module, comprising:
a plurality of solar cells, each solar cell comprising:
a photovoltaic device with a bus bar on a front side of said photovoltaic device;
a front tab attached to said front-side bus bar;
a superstrate bonded to said front side of said photovoltaic device, wherein said front tab is between said photovoltaic device and said superstrate; and
a rear tab attached to a rear side of said photovoltaic device; and
a module back sheet;
wherein said plurality of solar cells are arranged in a planar array and electrically interconnected, and wherein said module back sheet is bonded to the bottom side of said planar array of solar cells.

2. The photovoltaic module as in claim 1, wherein said superstrate is a glass sheet.

3. The photovoltaic module as in claim 1, wherein said superstrate is a polymer sheet.

4. The photovoltaic module as in claim 1, further comprising a bonding material between said superstrate and said photovoltaic device.

5. The photovoltaic module as in claim 1, wherein said module back sheet is bonded to said rear sides of said photovoltaic devices, said rear tabs being between said photovoltaic devices and said module back sheet.

6. The photovoltaic module as in claim 1, wherein spaces between said solar cells in said array are filled with a sealant.

7. The photovoltaic module as in claim 1, further comprising a module top sheet, said module top sheet being bonded to the top surfaces of said superstrates.

8. The photovoltaic module as in claim 7, wherein said module top sheet and said module back sheet are polymer sheets and said photovoltaic module is configured to be foldable along a line through said array, said line passing between solar cells.

9. The photovoltaic module as in claim 1, wherein each said solar cell further comprises a bottom sheet bonded to said rear side of said photovoltaic device, wherein said rear tab is between said photovoltaic device and said bottom sheet.

10. The photovoltaic module as in claim 9, wherein said module back sheet is bonded to the bottom surfaces of said bottom sheets.

11. The photovoltaic module as in claim 1, wherein said photovoltaic device is less than 50 microns thick.

12. A method of fabricating a photovoltaic module comprising:
providing a plurality of photovoltaic devices, each of said photovoltaic devices being attached at a rear side to a substrate, each of said photovoltaic devices having a bus bar on a front side;
for each of said photovoltaic devices, attaching a front tab to said bus bar and bonding a superstrate to said front side of said photovoltaic device, wherein said front tab is between said photovoltaic device and said superstrate;
for each of said photovoltaic devices with front tab and superstrate, separating said photovoltaic device from said substrate, to provide a plurality of solar cells, each solar cell including said photovoltaic cell, said front tab and said superstrate;
assembling said plurality of solar cells to form an array and electrically interconnecting said array; and
laminating said array to a module back sheet.

13. The method as in claim 12, wherein said providing a plurality of photovoltaic devices includes:
anodizing a single crystal silicon substrate to form a porous silicon layer on a top surface; and
growing very thin epitaxial silicon on said porous silicon layer in an epitaxial reactor.

14. The method as in claim 12, further comprising, for each of said plurality of solar cells, attaching a rear tab to a rear side of said solar cell.

15. The method as in claim 12, further comprising bonding a module top sheet to said array.

16. The method as in claim 12, further comprising filling spaces between said solar cells in said array with a sealant.

17. A method of fabricating a photovoltaic module comprising:
providing a photovoltaic device attached at a rear side to a substrate, forming a plurality of bus bars on a front side of said photovoltaic device, corresponding to a plurality of sub-devices;
attaching a plurality of front tabs to said plurality of bus bars and bonding a plurality of superstrates to said front side of said photovoltaic device, each superstrate corresponding to one of said sub-devices, wherein said plurality of front tabs are between said photovoltaic device and corresponding ones of said plurality of superstrates;
separating said plurality of sub-devices with tabs and superstrates from said substrate;
separating said plurality of sub-devices to provide a plurality of solar sub-cells;
assembling said plurality of solar sub-cells to form an array and electrically interconnecting said array; and
laminating said array to a module back sheet.

18. The method as in claim 17, further comprising, before said separating from said substrate, scribing said photovoltaic device to define said sub-devices.

19. The method as in claim 17, further comprising, after said separating from said substrate, scribing said photovoltaic device to define said sub-devices.

20. The method as in claim 19, wherein, during said scribing said plurality of superstrates are held by a fixture.
